(19) United States
(12) Patent Application Publication
(10) Pub. No.: US 2025/0199418 A1
(43) Pub. Date: Jun. 19, 2025

(54) MEASURING CONTRAST AND CRITICAL DIMENSION USING AN ALIGNMENT SENSOR

(71) Applicants: ASML Netherlands B.V., Veldhoven (NL); IMEC v.z.w., Leuven (BE)

(72) Inventors: Edouard André Marie Louis DURIAU, Veldhoven (NL); Cyrus Emil TABERY, San Jose, CA (US); Timothy Allan BRUNNER, Ridgefield, CT (US); Christopher P. AUSSCHNITT, Round Pond, ME (US); Vincent Patrick Thomas TRUFFERT, Woluwe-Saint-Pierre (BE)

(73) Assignees: ASML Netherlands B.V., Veldhoven (NL); IMEC v.z.w., Leuven (BE)

(21) Appl. No.: 18/876,101

(22) PCT Filed: Aug. 15, 2023
(86) PCT No.: PCT/EP2023/072449

§ 371 Date: Dec. 17, 2024

Related U.S. Application Data
(60) Provisional application No. 63/404,585, filed on Sep. 8, 2022.

(51) Int. Cl. G03F 7/00; G01B 11/27; G03F 9/00

(52) U.S. Cl. CPC G03F 7/70683; G01B 11/272; G03F 7/70625; G03F 7/706837; G03F 7/706851; G03F 9/7076; G03F 9/7088; G03F 9/7092

(57) ABSTRACT

A method can include directing radiation toward at least two targets using an optical scanning system so as to generate first and second portions of scattered radiation. A first target can include a plurality of first grating line structures including features having a first bias value. A second target can include a plurality of second grating line structures including features having a second bias value. The method can include detecting the first and second portions of scattered radiation, generating a first measurement signal indicative of a first target position based on the first bias features, and generating a second measurement signal indicative of a second target position based on the second bias features. The method can include analyzing an effect of the first and second bias values on the first and second positions to determine at least one property of the set of targets.

### CROSS-REFERENCE TO RELATED APPLICATIONS

This application claims priority of U.S. application 63/404,585 which was filed on Sep. 8, 2022 and which is incorporated herein in its entirety by reference.

### FIELD

The present disclosure relates to inspection systems, for example, an alignment system for measuring positions of targets in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which can be a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (photoresist or simply “resist”) provided on the substrate. In general, a single substrate will contain a network of adjacent target portions that are successively patterned. Known lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps can entail different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus can use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters can include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

Inspection is an important aspect of any lithographic process for ascertaining sub-nanometer accuracy when printing device patterns on a wafer. However, inspection measurements also add time to a fabrication process, thereby reducing the number of fabricated devices output by a lithographic process in a given timeframe. A lithographic process can rely on a plurality of inspection tools for different inspection needs (e.g., overlay, alignment positioning, critical dimension, or the like). Some inspection tools are more complex and time-consuming than others.

### SUMMARY

Accordingly, it is desirable to improve fabrication speed and throughput. For example, the number of inspection tools needed in a given lithographic process can be reduced and some inspection processes can be performed faster, based on aspects described herein.

In some aspects, a method can comprise directing radiation toward a set of targets comprising first and second targets using an optical scanning system so as to generate first and second portions of scattered radiation. The first target can comprise a plurality of first grating line structures comprising first bias features having a first bias value. The second target can comprise a plurality of second grating line structures comprising second bias features having a second bias value different from the first bias value. The directing of the radiation can comprise scanning the radiation across the set of targets. The method can further comprise detecting the first and second portions of scattered radiation using the optical scanning system. The method can further comprise generating a first measurement signal indicative of a first position of the first target based on the first bias features. The method can further comprise generating a second measurement signal indicative of a second position of the second target based on the second bias features. The method can further comprise, based on the first and second measurement signals, analyzing an effect of the first and second bias values on the first and second positions to determine at least one property of the set of targets.

In some aspects, a system can comprise an optical scanning system and a non-transitory computer-readable medium. The optical scanning system can comprise a radiation source, an optical device, and a detection system. The radiation source can be configured to generate radiation. The optical device can be configured to direct the radiation toward a set of targets comprising first and second targets to generate scattered radiation from the set of targets. The optical scanning system can be configured to actuate to scan the radiation across the set of targets. The detection system can be configured to, based on the scattered radiation, generate a first measurement signal indicative of a first position of the first target and generate a second measurement signal indicative of a second position of the second target. The non-transitory computer-readable medium can be configured to store instructions thereon that, when executed by one or more computing devices, cause the one or more computing devices to perform operations. The operations can comprise analyzing the first and second measurement signals. The first target can comprise a plurality of first grating line structures comprising first bias features having a first bias value that affects the first measurement signal. The second target can comprise a plurality of second grating line structures comprising second bias features having a second bias value that affects the second measurement signal. The second bias value can be different from the first bias value. The analyzing can comprise analyzing an effect of the first and second bias values on the first and second positions to determine at least one property of the set of targets.

In some aspects, a lithographic apparatus can comprise an illumination system, a projection system, an optical scanning system, and a non-transitory computer-readable medium. The illumination system can be configured to illuminate a pattern of a patterning device. The projection system can be configured to project an image of the pattern onto a substrate. The optical scanning system can comprise a radiation source, an optical device, and a detection system. The radiation source can be configured to generate radiation. The optical device can be configured to direct the radiation toward a set of targets comprising first and second targets to generate scattered radiation from the set of targets. The optical scanning system can be configured to actuate to scan the radiation across the set of targets. The detection system can be configured to, based on the scattered radiation, generate a first measurement signal indicative of a first position of the first target and generate a second measurement signal indicative of a second position of the second target. The non-transitory computer-readable medium can be configured to store instructions thereon that, when executed by one or more computing devices, cause the one or more computing devices to perform operations. The operations can comprise analyzing the first and second measurement signals. The first target can comprise a plurality of first grating line structures comprising first bias features having a first bias value that affects the first measurement signal. The second target can comprise a plurality of second grating line structures comprising second bias features having a second bias value that affects the second measurement signal. The second bias value can be different from the first bias value. The analyzing can comprise analyzing an effect of the first and second bias values on the first and second positions to determine at least one property of the set of targets.

In some aspects, a non-transitory computer-readable medium configured to store instructions thereon that, when executed by one or more computing devices, cause the one or more computing devices to perform operations. The operations can comprise analyzing first and second measurement signals from an optical scanning system configured to inspect a set of targets comprising first and second targets. The first measurement signal can be indicative of a first position of the first target based on scanning radiation across the first target. The first target can comprise a plurality of first grating line structures comprising first bias features having a first bias value that affects the first measurement signal. The second measurement signal can be indicative of a second position of the second target based on scanning radiation across the second target. The second target can comprise a plurality of second grating line structures comprising second bias features having a second bias value that affects the second measurement signal. The second bias value can be different from the first bias value. The analyzing can comprise analyzing an effect of the first and second bias values on the first and second positions to determine at least one property of the set of targets.

Further features of various aspects of the present disclosure are described in detail below with reference to the accompanying drawings. It is noted that the present disclosure is not limited to the specific aspects described herein. Such aspects are presented herein for illustrative purposes only. Additional aspects will be apparent to those skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable those skilled in the relevant art(s) to make and use aspects described herein.

FIG. 1A shows a reflective lithographic apparatus, according to some aspects.

FIG. 1B shows a transmissive lithographic apparatus, according to some aspects.

FIG. 2 shows more details of a reflective lithographic apparatus, according to some aspects.

FIG. 3 shows a lithographic cell, according to some aspects.

FIGS. 4A and 4B show inspection apparatuses, according to some aspects.

FIGS. 5A, 5B, 5C, 6A, 6B, and 6C show grating line structures that can be implemented as alignment targets, according to some aspects.

FIGS. 7A and 7B show targets, according to some aspects.

FIG. 8 shows a graph plot of alignment position measurements of different targets with different bias values, according to some aspects.

FIG. 9 shows a method for performing operations as described in reference to FIGS. 1-8, according to some aspects.

FIG. 10 shows a computer system 1000, according to some aspects.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

The aspects described herein, and references in the specification to “one aspect,” “an aspect,” “an exemplary aspect,” “an example aspect,” etc., indicate that the aspects described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of those skilled in the art to effect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The terms “about,” “approximately,” or the like can be used herein to indicate the value of a given quantity that can vary based on a particular technology. Based on the particular technology, the terms “about,” “approximately,” or the like can indicate a value of a given quantity that varies within, for example, 10-30% of the value (e.g., +10%, +20%, or +30% of the value).

Aspects of the present disclosure can be implemented in hardware, firmware, software, or any combination thereof. Aspects of the disclosure can also be implemented as instructions stored on a computer-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Furthermore, firmware, software, routines, and/or instructions can be described herein as performing certain actions. However, it should be appreciated that such descriptions are merely for convenience and that such actions result from computing devices, processors, controllers, or other devices executing the firmware, software, routines, instructions, etc. The term “machine-readable medium” can be interchangeable with similar terms, for example, “computer program product,” “computer-readable medium,” “non-transitory computer-readable medium,” or the like. The term “non-transitory” can be used herein to characterize one or more forms of computer readable media except for a transitory, propagating signal.

Before describing such aspects in more detail, however, it is instructive to present an example environment in which aspects of the present disclosure can be implemented.

### Example Lithographic Systems

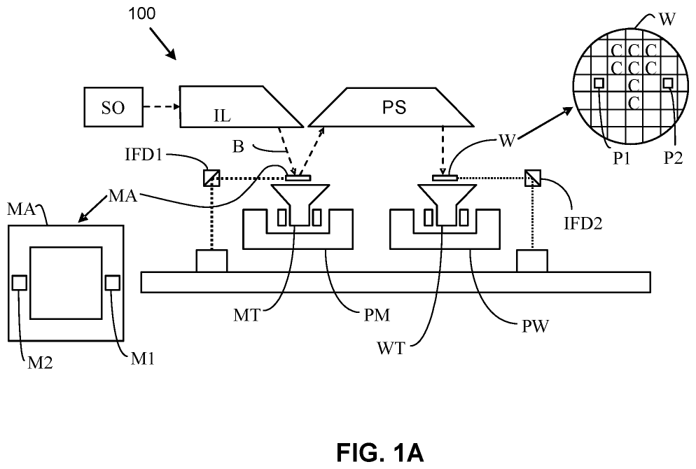

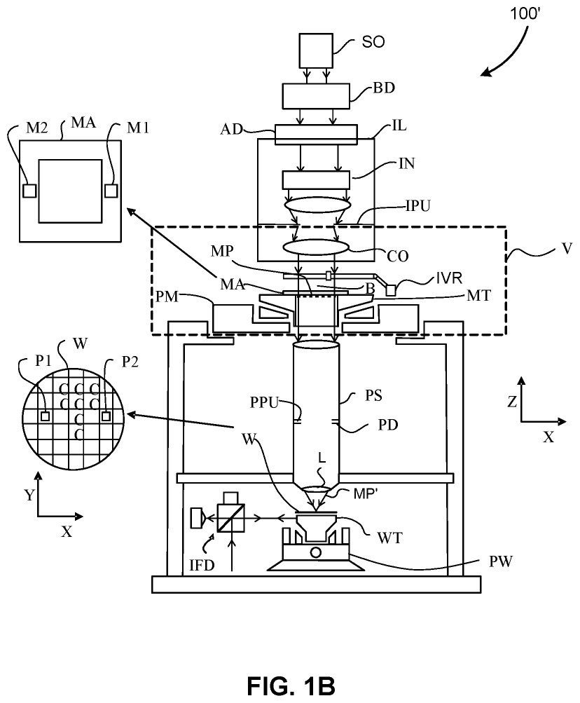

FIGS. 1A and 1B show a lithographic apparatus 100 and a lithographic apparatus 100′, respectively, in which aspects of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid. For example, a liquid can be located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. A radiation system can comprise the source SO, the illuminator IL, and/or the beam delivery system BD.

The illuminator IL can include an adjuster AD (in FIG. 1B) for adjusting the angular intensity distribution of the radiation beam. Generally, at least the outer and/or inner radial extent (commonly referred to as “6-outer” and “o-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture (e.g., using a lens or lens group L) the zeroth order diffracted beams, first order diffracted beams, and/or higher order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some aspects, astigmatism aberration can be reduced by providing radiation poles (not shown) in opposite quadrants of the illumination system pupil IPU. Further, in some aspects, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots can be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-) magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as needed after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In a further aspect, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

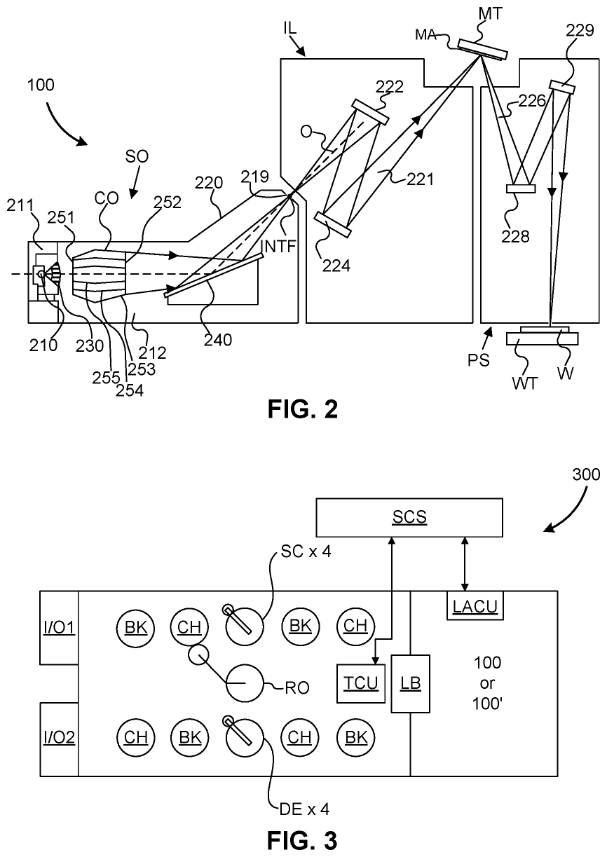

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 can be formed by a discharge produced plasma source. EUV radiation can be produced by a gas or vapor, for example Xe gas, Li vapor, or Sn vapor in which EUV radiation emitting plasma 210 is created to emit radiation in the EUV range of the electromagnetic spectrum. The EUV radiation emitting plasma 210 is created by, for example, an electrical discharge causing at least a partially ionized plasma. Partial pressures of, for example, 10 Pa of Xe, Li, Sn vapor, or any other suitable gas or vapor can be used for efficient generation of the radiation. In some aspects, a plasma of excited tin (Sn) (e.g., excited via a laser) is provided to produce EUV radiation.

The radiation emitted by the EUV radiation emitting plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which can be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the EUV radiation emitting plasma 210. Grating spectral filter 240 is used in particular for suppressing infra-red (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination optics unit IL and projection system PS. The grating spectral filter 240 can optionally be present, depending upon the type of lithographic apparatus. Further, there can be more mirrors present than those shown in the FIG. 2, for example there can be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Example Lithographic Cell

FIG. 3 shows a lithographic cell 300, also sometimes referred to a lithocell or cluster, according to some aspects. Lithographic apparatus 100 or 100′ can form part of lithographic cell 300. Lithographic cell 300 can also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Inspection Apparatus

In order to control the lithographic process to place device features accurately on the substrate, alignment marks are generally provided on the substrate, and the lithographic apparatus includes one or more inspection apparatuses for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement can be performed using the techniques described in U.S. Publication No. 2009/195768 A (Bijnen et al.), however. The full contents of both of these disclosures are incorporated herein by reference.

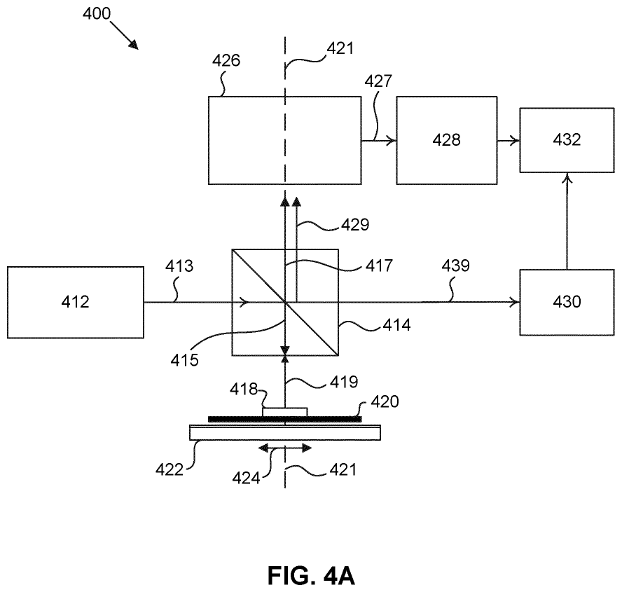

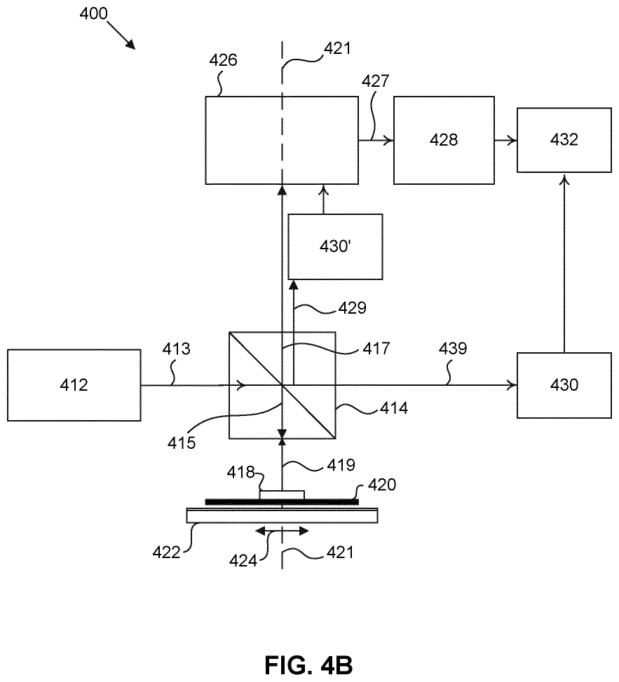

FIG. 4A shows a cross-sectional view of an inspection apparatus 400 that can be implemented as a part of lithographic apparatus 100 or 100′, according to some aspects. In some aspects, inspection apparatus 400 can be configured to align a substrate (e.g., substrate W) with respect to a patterning device (e.g., patterning device MA). Inspection apparatus 400 can be further configured to detect positions of alignment marks on the substrate and to align the substrate with respect to the patterning device or other components of lithographic apparatus 100 or 100′ using the detected positions of the alignment marks. Such alignment of the substrate can ensure accurate exposure of one or more patterns on the substrate.

The terms “inspection apparatus,” “metrology system,” or the like can be used herein to refer to, e.g., a device used for measuring a property of a structure (e.g., overlay sensor, critical dimension sensor, or the like), a device or system used in a lithographic apparatus to inspect an alignment of a wafer (e.g., alignment sensor), or the like.

In some aspects, inspection apparatus 400 can include an illumination system 412, a beam splitter 414, an interferometer 426, a detector 428, a beam analyzer 430, and an overlay calculation processor 432. Illumination system 412 can be configured to provide an electromagnetic narrow band radiation beam 413 having one or more passbands. In an example, the one or more passbands can be within a spectrum of wavelengths between about 500 nm to about 900 nm. In another example, the one or more passbands can be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values can improve long-term stability and accuracy of alignment systems (e.g., inspection apparatus 400) compared to the current alignment apparatuses.

In some aspects, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some aspects, alignment mark or target 418 can have one hundred and eighty degrees (i.e.,) 180° symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be (a) a resist layer grating comprising bars that are formed of solid resist lines, or (b) a product layer grating, or (c) a composite grating stack in an overlay target structure comprising a resist grating overlaid or interleaved on a product layer grating. The bars can alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, can be input to the reconstruction process, performed by processing unit PU, from knowledge of the printing step and/or other scatterometry processes.

In some aspects, beam splitter 414 can be further configured to receive diffraction radiation beam 419 and split diffraction radiation beam 419 into at least two radiation sub-beams, according to an aspect. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. Other optical arrangements can be used to obtain the similar result of illuminating alignment mark or target 418 on substrate 420 and detecting an image of alignment mark or target 418.

As illustrated in FIG. 4A, interferometer 426 can be configured to receive radiation sub-beam 417 and diffracted radiation sub-beam 429 through beam splitter 414. In an example aspect, diffracted radiation sub-beam 429 can be at least a portion of radiation sub-beam 415 that can be reflected from alignment mark or target 418. In an example of this aspect, interferometer 426 comprises any appropriate set of optical-elements, for example, a combination of prisms that can be configured to form two images of alignment mark or target 418 based on the received diffracted radiation sub-beam 429. It should be appreciated that a good quality image need not be formed. It can be enough to have the features of alignment mark 418 resolved. Interferometer 426 can be further configured to rotate one of the two images with respect to the other of the two images 180° and recombine the rotated and unrotated images interferometrically.

In some aspects, detector 428 can be configured to receive the recombined image via interferometer signal 427 and detect interference as a result of the recombined image when alignment axis 421 of inspection apparatus 400 passes through a center of symmetry (not shown) of alignment mark or target 418. Such interference can be due to alignment mark or target 418 being 180° symmetrical, and the recombined image interfering constructively or destructively, according to an example aspect. Based on the detected interference, detector 428 can be further configured to determine a position of the center of symmetry of alignment mark or target 418 and consequently, detect a position of substrate 420. According to an example, alignment axis 421 can be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further aspect, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data can be obtained using any type of alignment sensor, for example, a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some aspects, beam analyzer 430 can be configured to receive and determine an optical state of diffracted radiation sub-beam 439. The optical state can be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of substrate 420 can be accurately known with reference to stage 422. Alternatively, beam analyzer 430 can be configured to determine a position of inspection apparatus 400 or any other reference element such that the center of symmetry of alignment mark or target 418 can be known with reference to inspection apparatus 400 or any other reference element. Beam analyzer 430 can be a point or an imaging polarimeter with some form of wavelength-band selectivity. In some aspects, beam analyzer 430 can be directly integrated into inspection apparatus 400, or connected via fiber optics of several types: polarization preserving single mode, multimode, or imaging, according to other aspects.

In some aspects, beam analyzer 430 can be further configured to determine the overlay data between two patterns on substrate 420. One of these patterns can be a reference pattern on a reference layer. The other pattern can be an exposed pattern on an exposed layer. The reference layer can be an etched layer already present on substrate 420. The reference layer can be generated by a reference pattern exposed on the substrate by lithographic apparatus 100 and/or 100′. The exposed layer can be a resist layer exposed adjacent to the reference layer. The exposed layer can be generated by an exposure pattern exposed on substrate 420 by lithographic apparatus 100 or 100′. The exposed pattern on substrate 420 can correspond to a movement of substrate 420 by stage 422. In some aspects, the measured overlay data can also indicate an offset between the reference pattern and the exposure pattern. The measured overlay data can be used as calibration data to calibrate the exposure pattern exposed by lithographic apparatus 100 or 100′, such that after the calibration, the offset between the exposed layer and the reference layer can be minimized.

In some aspects, beam analyzer 430 can be further configured to determine a model of the product stack profile of substrate 420, and can be configured to measure overlay, critical dimension, and focus of target 418 in a single measurement. The product stack profile contains information on the stacked product such as alignment mark, target 418, or substrate 420, and can include mark process variation-induced optical signature metrology that is a function of illumination variation. The product stack profile can also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 can be further configured to process information related to a particular property of an exposed pattern in that layer. For example, beam analyzer 430 can process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some aspects, an array of detectors (not shown) can be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but each need separate pre-amps. The number of elements is therefore limited. CCD linear arrays offer many elements that can be read-out at high speed and are especially of interest if phase-stepping detection is used.

In some aspects, a second beam analyzer 430′ can be configured to receive and determine an optical state of diffracted radiation sub-beam 429, as shown in FIG. 4B. The optical state can be a measure of beam wavelength, polarization, or beam profile. Second beam analyzer 430′ can be identical to beam analyzer 430. Alternatively, second beam analyzer 430′ can be configured to perform one or more of the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ can also be configured to determine a position of inspection apparatus 400, or any other reference element, such that the center of symmetry of alignment mark or target 418 can be known with reference to inspection apparatus 400, or any other reference element. Second beam analyzer 430′ can be further configured to determine the overlay data between two patterns and a model of the product stack profile of substrate 420. Second beam analyzer 430′ can also be configured to measure overlay, critical dimension, and focus of target 418 in a single measurement.

In some aspects, second beam analyzer 430′ can be directly integrated into inspection apparatus 400, or it can be connected via fiber optics of several types: polarization preserving single mode, multimode, or imaging, according to other aspects. Alternatively, second beam analyzer 430′ and beam analyzer 430 can be combined to form a single analyzer (not shown) configured to receive and determine the optical states of both diffracted radiation sub-beams 429 and 439.

In some aspects, processor 432 receives information from detector 428 and beam analyzer 430. For example, processor 432 can be an overlay calculation processor. The information can comprise a model of the product stack profile constructed by beam analyzer 430. Alternatively, processor 432 can construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 can create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 can utilize the basic correction algorithm to characterize the inspection apparatus 400 with reference to wafer marks and/or alignment marks 418.

In some aspects, processor 432 can be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on substrate 420. Processor 432 can utilize a clustering algorithm to group the marks into sets of similar constant offset error, and create an alignment error offset correction table based on the information. The clustering algorithm can be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error can be deduced. Table 1 illustrates how this can be performed. The smallest measured overlay in the example shown is −1 nm. However this is in relation to a target with a programmed overlay of −30 nm. The process may have introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value can be taken to be the reference point and, relative to this, the offset can be calculated between measured overlay and that expected due to the programmed overlay. This offset determines the overlay error for each mark or the sets of marks with similar offsets. Therefore, in the Table 1 example, the smallest measured overlay was −1 nm, at the target position with programmed overlay of 30 nm. The difference between the expected and measured overlay at the other targets is compared to this reference. A table such as Table 1 can also be obtained from marks and target 418 under different illumination settings, the illumination setting, which results in the smallest overlay error, and its corresponding calibration factor, can be determined and selected. Following this, processor 432 can group marks into sets of similar overlay error. The criteria for grouping marks can be adjusted based on different process controls, for example, different error tolerances for different processes.

In some aspects, processor 432 can confirm that all or most members of the group have similar offset errors, and apply an individual offset correction from the clustering algorithm to each mark, based on its additional optical stack metrology. Processor 432 can determine corrections for each mark and feed the corrections back to lithographic apparatus 100 or 100′ for correcting errors in the overlay, for example, by feeding corrections into the inspection apparatus 400.

### Example Targets and Operations for Inspection

The terms “image contrast”, “contrast”, or the like, can be used herein to refer to the quality of the printed features. In lithography, the quality of the printed features can quantified using several metrics such as local CDU (“LCDU”), Line Width roughness (“LWR”), Normalized Image Log Slope (“NILS”), or the like. The term “contrast” can be used to encompass one or more of such metrics.

Conventional methods of measuring contrast can rely on expensive optional measurement hardware and is time consuming, thereby reducing throughput. In some aspects, the term “throughput” can be used to characterize a rate of lithographic fabrication. For example, throughput can refer to a rate at which lithographic fabrication is completed on wafers, a rate at which a wafer clears a particular fabrication step and moves to the next step, or the like. Throughput can be a performance marker of a lithographic apparatus. It is desirable for lithographic systems to output as many products as possible in as little time as possible. Lithographic fabrication can comprise several complex processes. Each part of the process can involve technical choices that balance quality (e.g., sub-nanometer accuracy, high yield) and drawbacks (e.g., slower fabrication, cost). For example, to improve pattern-transfer accuracy, lithography can include inspection of printed marks on a substrate. The inspection can be used to ascertain a conformity of a printed pattern on a substrate or to align a substrate in order to properly receive a new pattern. However, the added time of the inspection process can greatly affect throughput.

Measuring contrast across a wafer can be a desirable capability to include in lithographic tools. However, current methods to measure contrast such as e-beam approaches are too slow, expensive, and impractical for covering an entire wafer. Lack of image contrast quantification, calibration, and matching in deep UV (DUV) and extreme UV (EUV) lithographic tools generally leads to avoidable parts swap and un-resolvable issues.

While lithographic tools currently employ a variety of inspection tools for accomplishing a variety of inspection tasks, the inspection tools still lack contrast measurement capability. Tools like the aforementioned Yieldstar™ are image-based scatterometer inspection tools that can resolve critical dimensions of a printed structure. Image-based inspection involves analyzing a resolved image of the printed structure. On the other hand, an alignment sensor, like the aforementioned SMASH, uses a diffraction-based interferometry technique to analyze a modulation of an illumination signal from a target. From the analysis, a position of the target can be inferred. Conventional alignment sensors are not used for resolving critical dimensions and print quality because conventional alignment sensors are not optically designed to resolve an image with sub-nanometer features. While it can be possible to design such an alignment sensor for sub-nanometer image resolution (so that it can perform both alignment and image-based inspections) the cost and complexity of such a design is prohibitive.

However, in some aspects of the present disclosure, it is envisaged that diffraction-based alignment sensors can be endowed with contrast and critical dimension measurement capabilities in a manner that overcomes limitations of image resolution, for example, by clever use specially designed targets and post processing analysis. In this manner, lithographic machines with conventional alignment sensors can be conferred contrast and critical dimension functionalities that were previously unavailable. Furthermore, altering the target design and adding post processing operations (e.g., software) can be less costly and less complex compared to redesigning optical hardware, as well as faster than using other systems solely dedicated to critical dimension and contrast.

Before describing details of the aspects of the present disclosure, it is instructive to first consider an overview of how an alignment measurement can be performed. In some aspects, target 418 can be irradiated with illumination radiation to generate scattered radiation. With target 418 designed as a diffractive element (e.g., a grating), the scattered radiation can have one or more diffraction orders (e.g., ±1, ±2, or the like). The diffraction orders can be collected and sent to detector 428 (or a plurality of detectors). Detector 428 can generate measurement information in the form of a signal (e.g., a measurement signal). The measurement signal can be analyzed by a processor to determine a relative position of target 418 (e.g., a wafer alignment position). For alignment measurements, detector 428 can be a single-cell detector (i.e., a single pixel detector), a multi-pixel detector (e.g., a camera) capable of resolving an image, or the like. An alignment position can be extracted from the measurement signal by analyzing a total intensity on a detector (e.g., the measurement can work without needing to resolve individual pixels, hence single cell detectors can be used). For example, an alignment measurement can involve modulating the illumination (e.g., by scanning the illumination spot across target 418) and then analyzing characteristics of the AC measurement signal generated by the detector (e.g., amplitude, phase, or the like). An alignment position of target 418 can be derived from the characteristics of the AC measurement signal, for example, a phase of the signal.

Based on this method of extracting a position of a diffraction target, it can be deduced that alterations of diffraction properties of alignment marks can be exploited to shift the “apparent” (measured) position of the alignment marks in a deterministic manner. The shifting of the apparent position of a wafer can then be used to extract contrast and critical dimension information by analyzing apparent positions from alignment measurements.

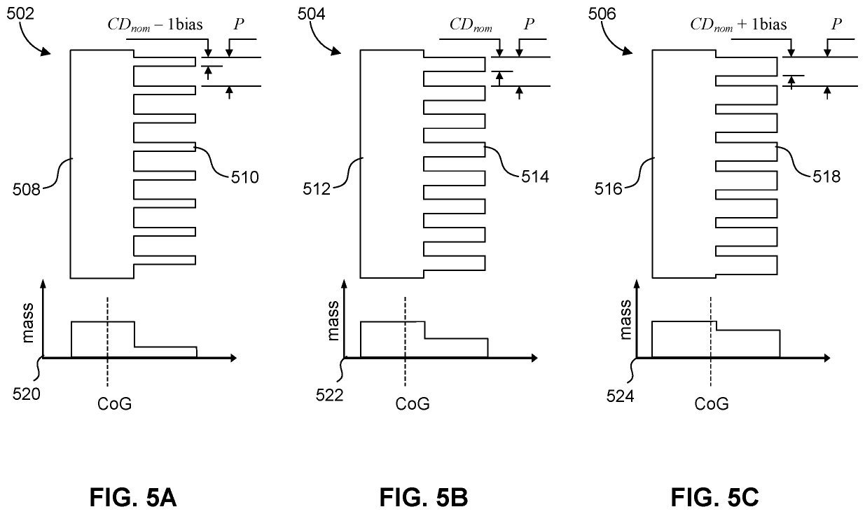

FIGS. 5A, 5B, and 5C show grating line structures 502, 504, and 506, respectively, that can be implemented as alignment targets, according to some aspects. In some aspects, grating line structure 502 can comprise a main body structure 508 and bias features 510 (e.g., first bias features). In some aspects of targets disclosed herein, a target can comprise an iteration of grating line structure 502. In contrast, a conventional grating can encompass iterations of main body structure 508 can be iterated without bias features 510. In some aspects, grating line structure 504 can comprise a main body structure 512 and bias features 514 (e.g., second bias features). Grating line structure 506 can comprise a main body structure 516 and bias features 518 (e.g., third bias features).

In some aspects, enumerative adjectives (e.g., “first,” “second,” “third,” or the like) can be used to distinguishing like elements without establishing an order, hierarchy, or quantity (unless otherwise noted). For example, the terms “first bias features” and “second bias features” can be used in a manner analogous to “ith bias features” and “jth bias features” to distinguish two bias features without specifying a particular order or hierarchy. Furthermore, an element in a drawing is not limited to any particular enumerative adjective. As a non-limiting example, bias features 510, 514, and 518 can be referred to as “sixth”, “first”, and “second” bias features, respectively.

FIG. 5B is directed to a nominal case, according to some aspects. In some aspects, bias features 514 can comprise periodic features having a pitch P and a bias of zero (can also be referred to as bias step 0). The measurement response that results from a zero bias target can be defined as corresponding to a nominal critical dimension CDₙₒₘ. The defining of zero bias (or any bias for that matter) can be achieved by, for example, a calibration process performed on a known reference or standard mark and implementing the results into the post-processing analysis of subsequent measurements. Furthermore, the defining of a nominal measured position of a target can also be achieved in this manner in order to account for any offsets resulting from the use of bias features in alignment targets. Graph plot 522 shows mass distribution corresponding to grating line structure 504. In the figures, center of gravity is denoted as “CoG.” The resulting location of the center of gravity is due to the mass being weighted more toward main body structure 512.

FIG. 5A is directed to a −1 bias step compared to the nominal case, according to some aspects. In some aspects, bias features 510 can comprise periodic features having a pitch P and a bias of −1 (can also be referred to as bias step −1). The measurement response that results from a −1 bias target can be defined in reference to a nominal critical dimension (e.g., CDₙₒₘ−1bias). In particular, bias features 510 can have a smaller duty cycle that reduces the width of bias features 510 compared to the nominal case of FIG. 5B. Graph plot 520 shows mass distribution corresponding to grating line structure 502. The resulting location of the center of gravity is due to the mass being weighted according to the effects of the −1 bias. Comparing to grating line structure 504 (nominal), the center of gravity for grating line structure 502 is more left-shifted due to the reduced mass on the right side resulting from the smaller duty cycle of bias features 510.

FIG. 5C is directed to a +1 bias step compared to the nominal case, according to some aspects. In some aspects, bias features 518 can comprise periodic features having a pitch P and a bias of +1 (can also be referred to as bias step +1). The measurement response that results from a +1 bias target can be defined in reference to a nominal critical dimension (e.g., CDₙₒₘ+1bias). In particular, bias features 518 can have a larger duty cycle that increases the width of bias features 518 compared to the nominal case of FIG. 5B. Graph plot 524 shows mass distribution corresponding to grating line structure 506. The resulting location of the center of gravity is due to the mass being weighted according to the effects of the +1 bias. Comparing to grating line structure 504 (nominal), the center of gravity for grating line structure 506 is more right-shifted due to the increased mass on the right side resulting from the larger duty cycle of bias features 518.

In some aspects, the grating line structures can be structures that have been deposited onto a substrate wafer. For example, the grating line structures can be made of photoresist that has survived a photoresist develop step. Conversely, the grating line structures can be a recess etched into a material. For example, the grating line structures can be fabricated by etching valleys into a photoresist, with the valleys having the profile of the grating line structures. It is to be appreciated that, in the latter case, the mass distribution in graph plots 520, 522, and 524 would be inverted so as to represent valleys rather than elevations and the center of gravity of the features would be represented by an analogous quantity for the negative space.

In some aspects, by leveraging fine bias features, grating line structures 502, 504, and 506 can have a structural bias that causes a shift of a center of gravity of the grating line structure. As alluded previously, an optical system (such as an alignment sensor) can be capable of resolving main body structures 508, 512, and 516, but may not be able to resolve bias features 510, 514, and 518 (and thus be incapable of resolving contrast or critical dimension). However, the shifts in center of gravity arising from the different biases can be exploited to infer contrast and/or critical dimension. Even if the alignment sensor cannot optically resolve bias features 510, 514, and 518 due to their small size, alignment position measurements can be sensitive to the shifts in the center of gravity of the grating line structure due to the bias features (resulting in a shifted apparent position of the measured target). Since the shift in center of gravity and the shift in apparent position have a deterministic relationship, the size and quality of bias features 510, 514, and 518 can be inferred by analyzing the apparent positions resulting from two or more targets having different bias features.

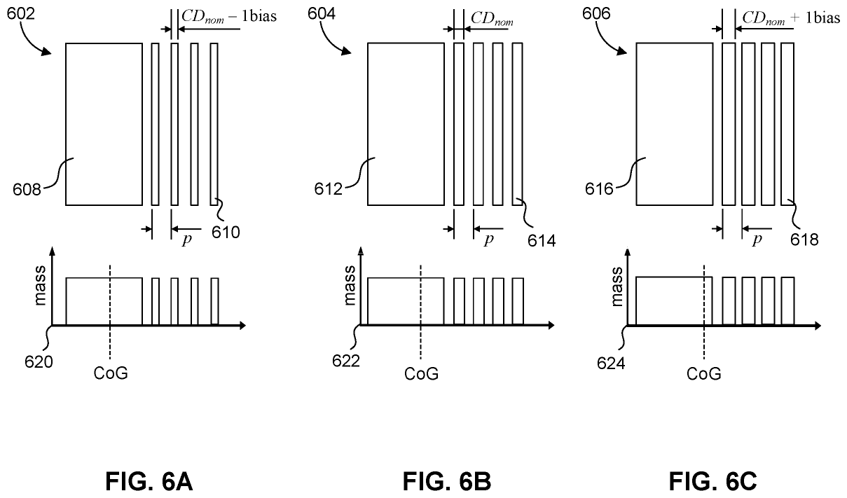

In some aspects, the bias feature designs are not limited to those shown in FIGS. 5A, 5B, and 5C. It should be appreciated that the principle of shifting the center of gravity can be implemented using other designs, for example, those shown in FIGS. 6A, 6B, and 6C.

FIGS. 6A, 6B, and 6C show grating line structures 602, 604, and 606, respectively, that can be implemented as alignment targets, according to some aspects. In some aspects, grating line structures 602, 604, and 606 can comprise structures and functions similar to grating line structures 502, 504, and 506, respectively (FIGS. 5A, 5B, and 5C). Therefore, unless otherwise noted, descriptions of elements of FIG. 5 can also apply to corresponding elements of FIGS. 6A, 6B, and 6C (e.g., reference numbers sharing the two right-most numeric digits) and will not be reintroduced in comprehensive detail. Elements in FIGS. 6A, 6B, and 6C can include main body structures 608, 612, and 616, bias features 610, 614, and 618, and graph plots 620, 622, and 624.

In some aspects, bias features 610, 614, and 618 can be aligned parallel to their respective main body structures, whereas the bias features in FIGS. 5A, 5B, and 5C were aligned perpendicular to their respective main body structures. In other words, the pitch P of bias features 610, 614, and 618 are parallel to a pitch of the primary, larger grating structure (whereas in FIGS. 5A, 5B, and 5C they were perpendicular). In a similar manner, bias features 610, 614, and 618 can achieve a shifting of center of gravity of the grating line structures, as shown in respective graph plots 620, 622, and 624. Designs of bias features are not limited to those shown in FIGS. 5A, 5B, 5C, 6A, 6B, and 6C. Other structural variations are envisaged (e.g., circles, dots, squares, arbitrary shapes, two-dimensional arrays, or the like) that achieve the shifting of the center of gravity of grating line structures according to a deterministic bias technique, thereby achieving a shift of the apparent position of targets that implement the grating line structures disclosed herein.

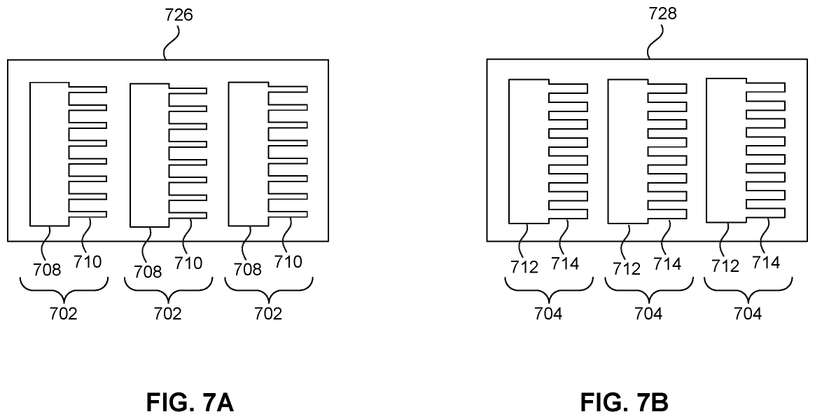

FIGS. 7A and 7B show targets 726 and 728, according to some aspects. In some aspects, targets 726 and 728 can comprise structures and functions similar to those described in reference to FIGS. 5A, 5B, and 5C. Therefore, unless otherwise noted, descriptions of elements of 5A, 5B, and 5C can also apply to corresponding elements of FIGS. 7A and 7B (e.g., reference numbers sharing the two right-most numeric digits) and will not be reintroduced in comprehensive detail. It is noted that other aspects of targets 726 and 728 are also envisaged using the structures and functions described in reference to FIGS. 6A, 6B, and 6C.

In some aspects, target 726 (e.g., first target) can comprise a plurality of grating line structures 702 (e.g., first grating line structures). Grating line structures 702 comprise main body structures 708 (e.g., first main body structures) and bias features 710 (e.g., first bias features 710). Bias features 710 can correspond to the case of bias step-1 (e.g., a first bias value; the bias value can be represented in a scale, length units, or the like). Target 728 (e.g., second target) can comprise a plurality of grating line structures 704 (e.g., second grating line structures). Grating line structures 704 comprise main body structures 712 (e.g., second main body structures) and bias features 714 (e.g., second bias features 710). Bias features 714 can correspond to the case of bias step 0 (e.g., a second bias value; the bias value can be represented in a scale, length units, or the like). It should be appreciated that a third target can comprise a design that corresponds to bias step +1. It should also be appreciated that more target designs are envisaged for other bias steps (e.g. −3, −2, +2, +3, or the like).

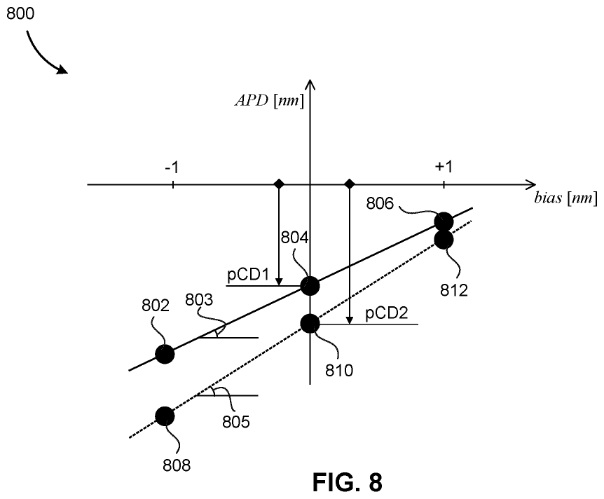

In some aspects, targets 726 and 728 can be inspected using an alignment inspection system (e.g., inspection system 400 (FIGS. 4A and 4B). For example, radiation can be directed toward targets 726 and 728 to generate corresponding first and second portions of scattered radiation. The scattered radiation can be detected (e.g., using detector 428 (FIG. 4)). A first measurement signal can be generated. The first measurement signal can be indicative of a position of target 726 (e.g., a first position) based on the shift provided by bias features 710. A second measurement signal can be generated. The second measurement signal can be indicative of a position of target 728 (e.g., a second position) based on the shift provided by bias features 714. The measurement signals can be analyzed. In particular, an effect of the first and second bias values on the first and second positions can be analyzed. From the analysis, a contrast and/or critical dimension of the targets can be determined. Two or more targets can be used (e.g., three targets are used to generate the data in FIG. 8).

FIG. 8 shows a graph plot 800 of alignment position measurements of different targets with different bias values, according to some aspects. In some aspects, the vertical axis of graph plot 800 can represent an apparent pattern displacement (APD) of measured targets. The horizontal axis of graph plot 800 can represent a bias value, which can be represented in real units (e.g., nm) or arbitrary steps (e.g. −1 bias, +1 bias, 0 bias, or the like). Different data points can correspond to different targets having different bias values (some example targets are discussed in reference to FIGS. 7A and 7B).

In some aspects, data points 802, 804, and 806 can represent measurements of targets having bias values −1, 0, and +1 respectively (e.g., a first set of targets). As a non-limiting example, three data points 802, 804, and 806 are shown, but it should be understood that aspects of the disclosure herein can work with two or more data points (e.g., four, five, six, or more data points, each associated with different bias values). At least one determinable property can be associated with the first set of targets. Properties of the second set of targets can be, for example, a critical dimension (e.g., a first critical dimension) and/or contrast. In FIG. 8, a critical dimension pCD1 is associated with data point 804-corresponding to a zero bias target. Since the relationship between bias value and shift of apparent position is deterministic, the analysis algorithm can be programmed to compare the measured alignment positions (APD) and bias values (e.g., compare 0 bias to −1 bias, compare 0 bias to a plurality of non-zero biases, or the like). Recalling that a conventional alignment sensor might not be able to resolve critical dimension structures, a critical dimension estimation can still be made by analyzing the shift in apparent position caused by different bias values (e.g., adding a given amount of nanometers of width to a bias feature deterministically enhances the shift of an apparent position). Furthermore, a slope of at least two of data points 802, 804, and 804 (e.g., slope 803) can be used by the analysis algorithm to determine contrast (which relates to a quality of printed features, as mentioned earlier).

In some aspects, data points 808, 810, and 812 can represent measurements of targets having bias values −1, 0, and +1 respectively (e.g., a second set of targets). At least one determinable property can be associated with the second set of targets. Properties of the second set of targets can be, for example, a critical dimension (e.g., a second critical dimension, pCD2 in FIG. 8), and/or contrast. And, similar to the use of data points data points 802, 804, and 806 and first set of targets, the second set of targets can be inspected by an alignment sensor and an analysis algorithm can extract critical dimension and/or contrast (e.g., based on slope 805). The scenario depicted by data points 808, 810, and 812 can be that of poorer contrast (e.g., a higher slope). Contrast can be a dominant and important indicator of the actual working of a printed device. When comparing measurements of two identical sets of biased targets, a higher slope can indicate a problem with exposure of photoresist (e.g., underexposed or overexposed).

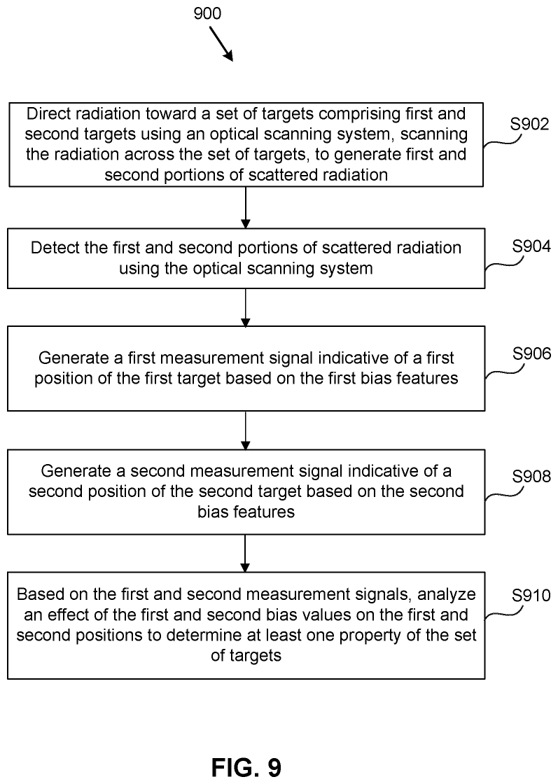

FIG. 9 shows a method 900 for performing operations as described in reference to FIGS. 1-8, according to some aspects. In some aspects, at step S902, a radiation source of an optical scanning system can be used to direct radiation toward a set of targets. Non-limiting examples of an optical scanning system can include inspection apparatus 400 (FIGS. 4A and 4B). As explained previously, an optical scanning system can scan an illumination spot across a grating target to ascertain properties of the target, such as an alignment position. The optical scanning system can be, for example, a diffraction-based alignment sensor or the like. The scanning optical system can actuate portions of its hardware to achieve the scanning. For example, the optical components of the optical scanning system can be moved relative to the target. In another example, the target (or target support platform) can be moved relative to the optical components of the scanning system. The set of targets can comprise a first and second target. For example, the set of targets can be targets 726 and 728 (FIGS. 7A and 7B). The first target can comprise a plurality of first grating line structures comprising first bias features having a first bias value so as to generate a first portion of scattered radiation. The second target can comprise a plurality of second grating line structures comprising second bias features having a second bias value different from the first bias value so as to generate a second portion of scattered radiation.

In some aspects, at step S904, the first and second portions of scattered radiation can be detected at a detector of the optical scanning system. The detection can be performed by, for example, detector 428 (FIGS. 4A and 4B). At step S906, a first measurement signal can be generated by the detector. The first measurement signal can be indicative of a first position of the first target based on the first bias features. At step S908, a second measurement signal can be generated by the detector. The second measurement signal can be indicative of a second position of the second target based on the second bias features. At step S910, based on the first and second measurement signals, an effect of the first and second bias values on the first and second positions can be analyzed to determine at least one property of the set of targets.

In some aspects, the at least one property can comprise a critical dimension of the set of targets, a contrast of the set of targets, or both. The analyzing at step S910 can comprise analyzing an apparent shift of the first position based on the first bias value, analyzing an apparent shift of the second position based on the second bias value, or analyzing both. Method 900 can further comprise determining the critical dimension, the contrast, or both based on the analyzing of the apparent shifts of the first, second, or first and second positions.

In some aspects, the set of targets can comprise a third target. The set of targets can improve additional targets (e.g., two or more targets). Additional targets can help enhance accuracy in quantifying the at least one property of the set of targets. Implementation of additional targets can be as described for the first and second targets (e.g., irradiated with radiation, generating a portion of scattered radiation, etc.).

In some aspects, the first bias features can comprise periodic structures having a pitch and a first duty cycle. The second bias features can comprise periodic structures having the same pitch, but a second duty cycle different from the first duty cycle. In some aspects, the pitch can be oriented approximately perpendicular to a pitch of the first grating line structures (e.g., as in FIGS. 5A, 5B, and 5C). In some aspects, the pitch can be oriented approximately parallel to a pitch of the first grating line structures (e.g., as in FIGS. 6A, 6B, and 6C).

In some aspects, the analyzing can be performed using a processor of a lithographic apparatus. A computer-readable medium can be used to store instructions to be executed by the processor in order to perform the method steps.

The method steps of FIG. 9 can be performed in any conceivable order and it is not required that all steps be performed. Moreover, the method steps of FIG. 9 described above merely reflect an example of steps and are not limiting. That is, further method steps and functions are envisaged based on aspects described in reference to FIGS. 1-8.

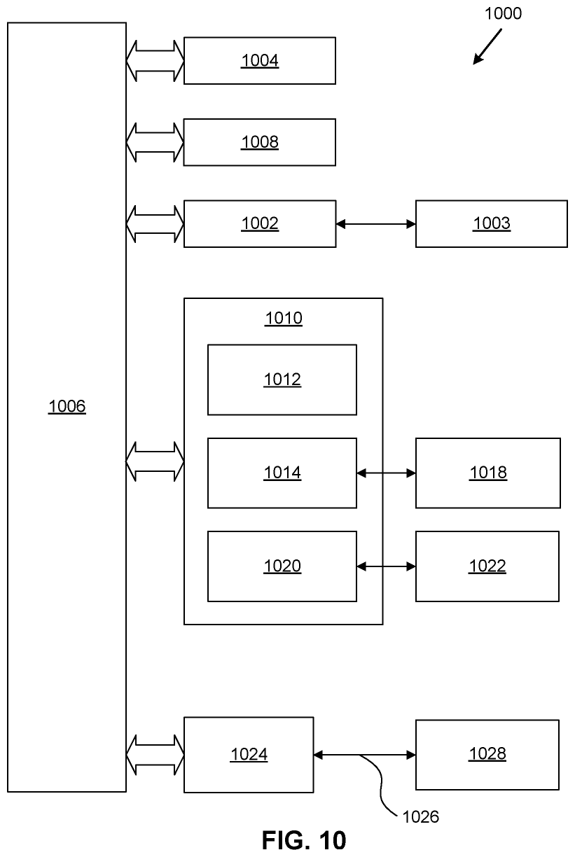

FIG. 10 shows a computer system 1000, according to some aspects. Various aspects and components therein can be implemented, for example, using computer system 1000 or any other well-known computer systems. For example, the method steps of FIG. 9 can be implemented via computer system 1000.

In some aspects, computer system 1000 can comprise one or more processors (also called central processing units, or CPUs), such as a processor 1004. Processor 1004 may be connected to a communication infrastructure or bus 1006.

In some aspects, one or more processors 1004 can each be a graphics processing unit (GPU). In some aspects, a GPU is a processor that is a specialized electronic circuit designed to process mathematically intensive applications. The GPU can have a parallel structure that is efficient for parallel processing of large blocks of data, such as mathematically intensive data common to computer graphics applications, images, videos, etc.

In some aspects, computer system 1000 can further comprise user input/output device(s) 1003, such as monitors, keyboards, pointing devices, etc., that communicate with communication infrastructure 1006 through user input/output interface(s) 1002. Computer system 1000 can further comprise a main or primary memory 1008, such as random access memory (RAM). Main memory 1008 can comprise one or more levels of cache. Main memory 1008 has stored therein control logic (i.e., computer software) and/or data.

In some aspects, computer system 1000 can further comprise one or more secondary storage devices or memory 1010. Secondary memory 1010 can comprise, for example, a hard disk drive 1012 and/or a removable storage device or drive 1014. Removable storage drive 1014 can be a floppy disk drive, a magnetic tape drive, a compact disk drive, an optical storage device, tape backup device, and/or any other storage device/drive. Removable storage drive 1014 can interact with a removable storage unit 1018. Removable storage unit 1018 can comprise a computer usable or readable storage device having stored thereon computer software (control logic) and/or data. Removable storage unit 1018 can be a floppy disk, magnetic tape, compact disk, DVD, optical storage disk, and/any other computer data storage device. Removable storage drive 1014 reads from and/or writes to removable storage unit 1018 in a well-known manner.

In some aspects, secondary memory 1010 can comprise other means, instrumentalities or other approaches for allowing computer programs and/or other instructions and/or data to be accessed by computer system 1000. Such means, instrumentalities or other approaches can comprise, for example, a removable storage unit 1022 and an interface 1020. Examples of the removable storage unit 1022 and the interface 1020 can comprise a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

In some aspects, computer system 1000 can further comprise a communication or network interface 1024. Communication interface 1024 enables computer system 1000 to communicate and interact with any combination of remote devices, remote networks, remote entities, etc. (individually and collectively referenced by reference number 1028). For example, communication interface 1024 can allow computer system 1000 to communicate with remote devices 1028 over communications path 1026, which can be wired and/or wireless, and which can comprise any combination of LANs, WANs, the Internet, etc. Control logic and/or data can be transmitted to and from computer system 1000 via communications path 1026.

In some aspects, a non-transitory, tangible apparatus or article of manufacture comprising a non-transitory, tangible computer useable or readable medium having control logic (software) stored thereon is also referred to herein as a computer program product or program storage device. This includes, but is not limited to, computer system 1000, main memory 1008, secondary memory 1010, and removable storage units 1018 and 1022, as well as tangible articles of manufacture embodying any combination of the foregoing. Such control logic, when executed by one or more data processing devices (such as computer system 1000), causes such data processing devices to operate as described herein.

Based on the teachings contained in this disclosure, it will be apparent to those skilled in the relevant art(s) how to make and use aspects of this disclosure using data processing devices, computer systems and/or computer architectures other than that shown in FIG. 10. In particular, aspects described herein can operate with software, hardware, and/or operating system implementations other than those described herein.

The embodiments may further be described using the following clauses:

1. A method comprising:
directing radiation toward a set of targets comprising first and second targets using an optical scanning system, wherein
the first target comprises a plurality of first grating line structures comprising first bias features having a first bias value so as to generate a first portion of scattered radiation,
the second target comprises a plurality of second grating line structures comprising second bias features having a second bias value different from the first bias value so as to generate a second portion of scattered radiation, and
the directing of the radiation comprises scanning the radiation across the set of targets;
detecting the first and second portions of scattered radiation using the optical scanning system;
generating a first measurement signal indicative of a first position of the first target based on the first bias features;
generating a second measurement signal indicative of a second position of the second target based on the second bias features; and
based on the first and second measurement signals, analyzing an effect of the first and second bias values on the first and second positions to determine at least one property of the set of targets.

2. The method of clause 1, further comprising determining the at least one property, wherein the at least one property comprises a critical dimension of the set of targets, a contrast of the set of targets, or the critical dimension and contrast.

3. The method of clause 1, wherein the analyzing of the effect of the first and second bias values comprises analyzing an apparent shift of the first position based on the first bias value, analyzing an apparent shift of the second position based on the second bias value, or analyzing the apparent shifts of the first and second positions.

4. The method of clause 3, the method further comprises determining a critical dimension, a contrast, or the critical dimension and contrast based on the analyzing of the apparent shifts of the first, second, or first and second positions.

5. The method of clause 1, wherein:
the set of targets comprises a third target;
the third target comprises a plurality of third grating line structures comprising third bias features having a third bias value so as to generate a third portion of scattered radiation;
the third bias value is different from the first and second bias values;
   the method further comprises:
detecting the third portion of scattered radiation; and
generating a third measurement signal indicative of a third position of the third target based on the third bias features;
   the analyzing is further based on the third measurement signal; and
the analyzing further comprises analyzing an effect of the third bias value on the third position to determine the at least one property.

6. The method of clause 1, wherein:
the first bias features comprise periodic structures having a pitch and a first duty cycle;
the second bias features comprise periodic structures having the pitch and a second duty cycle; and
the analyzing is further based on a difference of the first and second duty cycles.

7. The method of clause 6, wherein the pitch is oriented approximately perpendicular to a pitch of the first grating line structures.

8. The method of clause 6, wherein the pitch is oriented approximately parallel to a pitch of the first grating line structures.

9. The method of clause 1, wherein:
the optical scanning system comprises a diffraction-based alignment sensor;
the detecting comprises detecting the first and second portions of scattered radiation using the diffraction-based alignment sensor.

10. The method of clause 9, wherein the analyzing is performed by a processor of a lithographic apparatus.

11. A system comprising:
an optical scanning system comprising:
a radiation source configured to generate radiation;
an optical device configured to direct the radiation toward a set of targets comprising first and second targets to generate scattered radiation from the set of targets, wherein the optical scanning system is configured to actuate to scan the radiation across the set of targets;
a detection system configured to, based on the scattered radiation:
generate a first measurement signal indicative of a first position of the first target; and
generate a second measurement signal indicative of a second position of the second target; and
a non-transitory computer-readable medium configured to store instructions thereon that, when executed by one or more computing devices, cause the one or more computing devices to perform operations comprising:
analyzing the first and second measurement signals, wherein
the first target comprises a plurality of first grating line structures comprising first bias features having a first bias value that affects the first measurement signal,
the second target comprises a plurality of second grating line structures comprising second bias features having a second bias value that affects the second measurement signal, and
the second bias value is different from the first bias value, and
the analyzing comprises analyzing an effect of the first and second bias values on the first and second positions to determine at least one property of the set of targets.

12. The system of clause 11, wherein the non-transitory computer-readable medium is further configured to store further instructions such that the operations further comprise determining the at least one property, wherein the at least one property comprises a critical dimension of the set of targets, a contrast of the set of targets, or the critical dimension and contrast.

13. The system of clause 11, wherein the non-transitory computer-readable medium is further configured to store further instructions such that the analyzing of the effect of the first and second bias values comprises analyzing an apparent shift of the first position based on the first bias value, analyzing an apparent shift of the second position based on the second bias value, or analyzing the apparent shifts of the first and second positions.

14. The system of clause 13, wherein the non-transitory computer-readable medium is further configured to store further instructions such that the operations further comprise determining a critical dimension, a contrast, or the critical dimension and contrast based on the analyzing of the apparent shifts of the first, second, or first and second positions.

15. The system of clause 11, wherein:
the set of targets comprises a third target;
the scattered radiation comprises radiation from the third target;
the detection system is further configured to, based on the scattered radiation, generate a third measurement signal indicative of a third position of the third target;
the third target comprises a plurality of third grating line structures comprising third bias features having a third bias value that affects the third measurement signal;
the non-transitory computer-readable medium is further configured to store further instructions such that the analyzing further comprises analyzing an effect of the third bias value on the third position to determine the at least one property; and
the third bias value is different from the first and second bias values.

16. The system of clause 11, wherein:
the non-transitory computer-readable medium is further configured to store further instructions such that the analyzing based on a difference of a first duty cycle and a second duty cycle;
the first bias features comprise periodic structures having a pitch and the first duty cycle; and
the second bias features comprise periodic structures having the pitch and the second duty cycle.

17. The system of clause 16, wherein the pitch is oriented approximately perpendicular to a pitch of the first grating line structures.

18. The system of clause 16, wherein the pitch is oriented approximately parallel to a pitch of the first grating line structures.

19. The system of claim 11, wherein the inspection system is a diffraction-based alignment sensor.

20. A lithographic apparatus comprising:
an illumination system configured to illuminate a pattern of a patterning device;
a projection system configured to project an image of the pattern onto a substrate;
an optical scanning system comprising:
a radiation source configured to generate radiation;
an optical device configured to direct the radiation toward a set of targets comprising first and second targets to generate scattered radiation from the set of targets, wherein the optical scanning system is configured to actuate to scan the radiation across the set of targets; and
a detection system configured to, based on the scattered radiation:
generate a first measurement signal indicative of a first position of the first target; and
generate a second measurement signal indicative of a second position of the second target; and
a non-transitory computer-readable medium configured to store instructions thereon that, when executed by one or more computing devices, cause the one or more computing devices to perform operations comprising:
analyzing the first and second measurement signals, wherein
the first measurement signal is indicative of a first position of the first target,
the first target comprises a plurality of first grating line structures comprising first bias features having a first bias value that affects the first measurement signal,
the second measurement signal comprises information of a second position of the second target,
the second target comprises a plurality of second grating line structures comprising second bias features having a second bias value that affects the second measurement signal,
the second bias value is different from the first bias value, and
the analyzing comprises analyzing an effect of the first and second bias values on the first and second positions to determine at least one property of the set of targets.

21. A non-transitory computer-readable medium configured to store instructions thereon that, when executed by one or more computing devices, cause the one or more computing devices to perform operations comprising:
analyzing first and second measurement signals from an optical scanning system configured to inspect a set of targets comprising first and second targets, wherein
the first measurement signal is indicative of a first position of the first target based on scanning radiation across the first target,
the first target comprises a plurality of first grating line structures comprising first bias features having a first bias value that affects the first measurement signal,
the second measurement signal is indicative of a second position of the second target based on scanning radiation across the second target,
the second target comprises a plurality of second grating line structures comprising second bias features having a second bias value that affects the second measurement signal,
the second bias value is different from the first bias value, and
the analyzing comprises analyzing an effect of the first and second bias values on the first and second positions to determine at least one property of the set of targets.

The terms “radiation,” “beam,” “light,” “illumination,” or the like can be used herein to refer to one or more types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-100 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some aspects, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

Although some aspects of the present disclosure are described in the context of lithographic apparatuses in the manufacture of ICs, it should be understood that lithographic apparatuses described herein can be used in other applications, for example, in the manufacture of integrated optical systems, guidance and detection patterns for magnetic domain memories, flat-panel displays, LCDs, thin-film magnetic heads, etc. Those skilled in the art will appreciate that, in the context of such alternative applications, any use of the terms “wafer” or “die” herein can be considered as specific examples of the more general terms “substrate” or “target portion”, respectively. A substrate can be processed before or after exposure in, for example, a track unit (a tool that typically applies a layer of resist to a substrate and develops the exposed resist) and/or a metrology unit. Where applicable, aspects disclosed herein can be applied to such and other substrate processing tools. Furthermore, a substrate can be processed more than once, for example in order to create a multi-layer IC, so that the term substrate used herein can also refer to a substrate that already contains multiple processed layers.

Furthermore, although some aspects of the present disclosure are described in the context of optical lithography, it should be understood that aspects of the present disclosure are not limited to optical lithography. For example, in imprint lithography, a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed. The foregoing description of specific aspects will so fully reveal the general nature of the present disclosure that others can, by applying knowledge within the skill of the art, readily modify and/or adapt for various applications such specific aspects, without undue experimentation and without departing from the general concept of the present disclosure. Therefore, such adaptations and modifications are intended to be within the meaning and range of equivalents of the disclosed aspects, based on the teaching and guidance presented herein.

It is to be understood that the Detailed Description section, and not the Summary and Abstract sections, is intended to be used to interpret the claims. The Summary and Abstract sections can set forth one or more, but not necessarily all, aspects of the present disclosure as contemplated by the inventor(s), and thus, are not intended to limit the present disclosure and the appended claims in any way. The breadth and scope of the protected subject matter should not be limited by any of the above-described aspects, but should be defined in accordance with the following claims and their equivalents.

1. A method comprising:
directing radiation toward a set of targets comprising first and second targets using an optical scanning system, wherein
the first target comprises a plurality of first grating line structures comprising first bias features having a first bias value so as to generate a first portion of scattered radiation,
the second target comprises a plurality of second grating line structures comprising second bias features having a second bias value different from the first bias value so as to generate a second portion of scattered radiation, and
the directing of the radiation comprises scanning the radiation across the set of targets;
detecting the first and second portions of scattered radiation using the optical scanning system;
generating a first measurement signal indicative of a first position of the first target based on the first bias features;
generating a second measurement signal indicative of a second position of the second target based on the second bias features; and
based on the first and second measurement signals, analyzing an effect of the first and second bias values on the first and second positions to determine at least one property of the set of targets.

2. The method of claim 1, further comprising determining the at least one property, wherein the at least one property comprises a critical dimension of the set of targets, a contrast of the set of targets, or the critical dimension and contrast.

3. The method of claim 1, wherein the analyzing of the effect of the first and second bias values comprises analyzing an apparent shift of the first position based on the first bias value, analyzing an apparent shift of the second position based on the second bias value, or analyzing the apparent shifts of the first and second positions.

4. The method of claim 3, the method further comprises determining a critical dimension, a contrast, or the critical dimension and contrast based on the analyzing of the apparent shifts of the first, second, or first and second positions.

5. The method of claim 1, wherein:
the set of targets comprises a third target;
the third target comprises a plurality of third grating line structures comprising third bias features having a third bias value so as to generate a third portion of scattered radiation;
the third bias value is different from the first and second bias values;
the method further comprises:
detecting the third portion of scattered radiation; and
generating a third measurement signal indicative of a third position of the third target based on the third bias features;
the analyzing is further based on the third measurement signal; and
the analyzing further comprises analyzing an effect of the third bias value on the third position to determine the at least one property.

6. The method of claim 1, wherein:
the first bias features comprise periodic structures having a pitch and a first duty cycle;
the second bias features comprise periodic structures having the pitch and a second duty cycle; and
the analyzing is further based on a difference of the first and second duty cycles.

7. The method of claim 6, wherein the pitch is oriented approximately perpendicular to a pitch of the first grating line structures.

8. The method of claim 6, wherein the pitch is oriented approximately parallel to a pitch of the first grating line structures.

9. The method of claim 1, wherein:
the optical scanning system comprises a diffraction-based alignment sensor;
the detecting comprises detecting the first and second portions of scattered radiation using the diffraction-based alignment sensor.

10. The method of claim 9, wherein the analyzing is performed by a processor of a lithographic apparatus.

11. A system comprising:
an optical scanning system comprising:
a radiation source configured to generate radiation;
an optical device configured to direct the radiation toward a set of targets comprising first and second targets to generate scattered radiation from the set of targets, wherein the optical scanning system is configured to actuate to scan the radiation across the set of targets;
a detection system configured to, based on the scattered radiation:
generate a first measurement signal indicative of a first position of the first target; and
generate a second measurement signal indicative of a second position of the second target; and
a non-transitory computer-readable medium configured to store instructions thereon that, when executed by one or more computing devices, cause the one or more computing devices to perform operations comprising:
analyzing the first and second measurement signals, wherein
the first target comprises a plurality of first grating line structures comprising first bias features having a first bias value that affects the first measurement signal,
the second target comprises a plurality of second grating line structures comprising second bias features having a second bias value that affects the second measurement signal, and
the second bias value is different from the first bias value, and
the analyzing comprises analyzing an effect of the first and second bias values on the first and second positions to determine at least one property of the set of targets.

12. The system of claim 11, wherein the non-transitory computer-readable medium is further configured to store further instructions such that the operations further comprise determining the at least one property, wherein the at least one property comprises a critical dimension of the set of targets, a contrast of the set of targets, or the critical dimension and contrast.

13. The system of claim 11, wherein the non-transitory computer-readable medium is further configured to store further instructions such that the analyzing of the effect of the first and second bias values comprises analyzing an apparent shift of the first position based on the first bias value, analyzing an apparent shift of the second position based on the second bias value, or analyzing the apparent shifts of the first and second positions.

14. The system of claim 13, wherein the non-transitory computer-readable medium is further configured to store further instructions such that the operations further comprise determining a critical dimension, a contrast, or the critical dimension and contrast based on the analyzing of the apparent shifts of the first, second, or first and second positions.

15. The system of claim 11, wherein:
the set of targets comprises a third target;
the scattered radiation comprises radiation from the third target;
the detection system is further configured to, based on the scattered radiation, generate a third measurement signal indicative of a third position of the third target;
the third target comprises a plurality of third grating line structures comprising third bias features having a third bias value that affects the third measurement signal;
the non-transitory computer-readable medium is further configured to store further instructions such that the analyzing further comprises analyzing an effect of the third bias value on the third position to determine the at least one property; and
the third bias value is different from the first and second bias values.
